(19) United States
(12) Patent Application Publication
(10) Pub. No.: US 2025/0142836 A1
(43) Pub. Date: May 1, 2025

(54) NEURAL NETWORK CIRCUIT AND METHOD FOR FORMING THE SAME

(71) Applicant: TAIWAN SEMICONDUCTOR MANUFACTURING COMPANY, LTD., Hsinchu (TW)

(72) Inventors: Yu-Sheng CHEN, Taoyuan City (TW); Kuen-Yi CHEN, Hsinchu City (TW); Yi-Hsuan CHEN, Taoyuan City (TW); Hsin Heng WANG, Hsinchu County (TW); Yi Ching ONG, Hsinchu (TW); Kuo-Ching HUANG, Hsinchu City (TW)

(73) Assignee: TAIWAN SEMICONDUCTOR MANUFACTURING COMPANY, LTD., Hsinchu (TW)

(21) Appl. No.: 18/498,596

(22) Filed: Oct. 31, 2023

(51) Int. Cl. H10B 61/00; G06N 3/047; H10B 63/00

(52) U.S. Cl. CPC H10B 61/22; G06N 3/047; H10B 63/30

(57) ABSTRACT

A neural network circuit includes an input neuron layer comprises a plurality of first neurons. A hidden neuron layer includes a plurality of second neurons, wherein each of the second neurons comprises a probabilistic bit having a time-varying resistance. The probabilistic bit is a magnetic tunnel junction structure comprises a pinned layer, a free layer, and a tunneling barrier layer between the pinned layer and the free layer. A weight matrix comprising a plurality of synapse units, each of the synapse units connecting one of the plurality of first neurons to a corresponding one of the plurality of first neurons.

### BACKGROUND

Artificial neural networks (ANN) are one of the main tools used in machine learning, inspired by animal brains. A neural network consists of input and output layers. In common ANN implementations, the signal at a connection between artificial neurons is a real number, and the output of each artificial neuron is computed by some non-linear function of the sum of its inputs. The connections between artificial neurons are called “synapses”. Artificial neurons and synapses typically have a weight that adjusts as learning proceeds. The weight increases or decreases indicating an increase or decrease of the strength of the signal at a connection between two neurons. Artificial neurons may have a threshold such that the signal is only sent if the aggregate signal crosses that threshold. Typically, artificial neurons are aggregated into layers. Different layers may perform different kinds of transformations on their inputs. Signals travel from the first layer (the input layer) to the last layer (the output layer), possibly after traversing the layers multiple times.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a neural network in accordance with some embodiments.

FIG. 2 is a circuit diagram of a neural network in accordance with some embodiments.

FIG. 3 is a cross-sectional view of a neural network in accordance with some embodiments.

FIGS. 4 to 8 illustrate a neural network in various stages of fabrication in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Analog computing is useful in a wide range of applications, especially in computations, simulations and implementations relating to complex systems, such as neurological systems. For example, artificial neural networks (or simply “neural networks” as used in this disclosure) have been used to achieve machine learning in artificial intelligence (“AI”) systems. One example type of neural network includes logically sequentially arranged layers of nodes, or artificial neurons. The layers include an input layer, an output layer, a one or more intermediate layers (so-called “hidden layers”). The nodes in input layer receive input signals from external sources, akin to signals from synapse in biological systems, and output signals to the hidden layers. Each node in a hidden layer receives signals from the nodes in the immediate upstream layer and outputs signals to the nodes in the immediate downstream layer. Each node in the output layer receives the signals from the last hidden layer and produces an output signal. In some example neural networks, the output signal from each node in a layer is a function of the weighted sum of signals from all nodes in the upstream layer.

In some embodiments, analog computing system includes a resistor network connecting successive layers of nodes, such as between the input layer and the first hidden layer. In these embodiments, each node in a layer is connected to several, or all, of the nodes in the upstream layer through a respective resistive assembly, the resistance of which is adjustable. The signal, in the form of the current, generated at each node is thus the sum of the products between the currents at the nodes of the upstream layer and the conductances of the respective resistive assemblies. The conductances are therefore the weights for the signals from the respective nodes in the upstream layer.

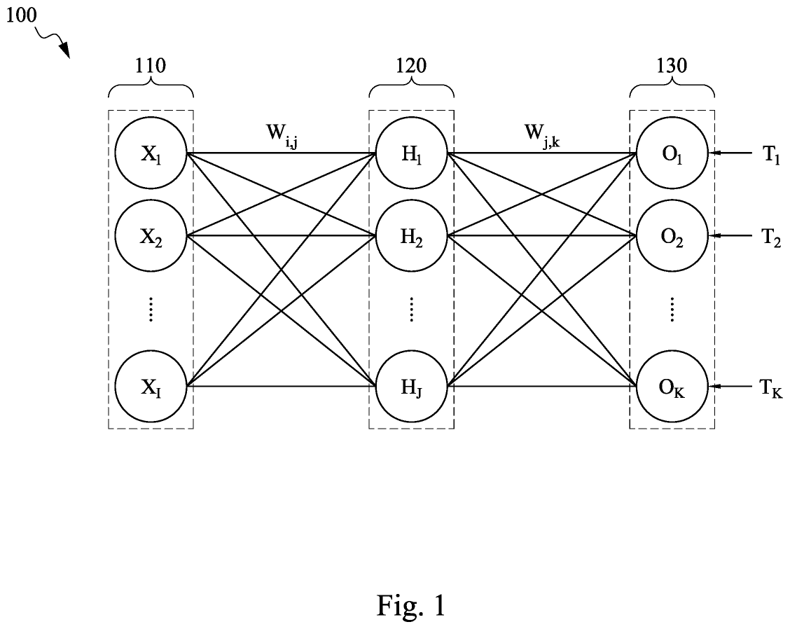

FIG. 1 is a block diagram of a neural network in accordance with some embodiments. Shown there is a neural network 100. The neural network 100 of the present disclosure includes an input neuron layer 110, a hidden neuron layer 120, and an output neuron layer 130. The input neuron layer 110 includes a plurality of neurons X₁-X_{I}, the hidden neuron layer 120 includes a plurality of neurons H₁-H_{J}, and the output neuron layer 130 includes a plurality of neurons O₁-O_{K}. In some embodiments, two adjacent neuron layers are referred to as pre-neuron and post-neuron layers along a forward propagation direction, and are fully connected to each other. For illustration, the neuron X₁ in the input neuron layer 110 is connected to each of the neurons H₁-H_{J}, the neuron X₂ in the input neuron layer 110 is also connected to each of the neurons H₁-H_{J}, and each of the rest neurons X_{I} in the input neuron layer 110 is also connected to all of the neurons H₁-H_{J}. The above-mentioned connection manner is regarded as each one neuron X₁ being fully connected to the neurons H₁-H_{J}. Here, a single neuron may be connected to many other neurons. Neurons are connected to one another through connections referred to as “synapse units.” A synapse unit is a structure that permits a neuron to pass an electrical or chemical signal to another neuron.

In some embodiments, the input neuron layer 110 and the hidden neuron layer 120 are two adjacent neuron layers, and input data are inputted from the input neuron layer 110 to the hidden neuron layer 120. The input data is transformed into a binary number or other suitable digital type. Subsequently, the binary number is inputted into the neurons X₁-X_{I} of the input neuron layer 110. The input neuron layer 110 and the hidden neuron layer 120 are fully connected with each other, and two connected neurons in the input neuron layer 110 and the hidden neuron layer 120 have a weight W_{i,j}. For instance, the neuron X₁ in the input neuron layer 110 and the neuron H₁ in the hidden neuron layer 120 are connected to each other, and there is a weight W_{1,1} between the neuron X₁ and the neuron H₁. Each of the neurons H₁-H_{J} in the hidden neuron layer 120 receives products of every input data and the weight W_{i,j}, and the product is referred to as a weight sum in some embodiments. For example, for neuron H₁, the neuron H₁ receive the weight sum X₁*W_{1,1}+X₂*W_{2,1}+ . . . +X_{I}*W_{I,1}. For neuron H₂, the neuron H₂ receive the weight sum X₁*W_{1,2}+X₂*W_{2,2}+ . . . +X_{I}*W_{I,2}. For neuron H_{J}, the neuron H_{J} receive the weight sum X₁*W_{1,J}+X₂*W_{2,J}+ . . . +X_{I}*W_{I,J}.

In various embodiments, the hidden neuron layer 120 and the output neuron layer 130 are two adjacent neuron layers, and the input data are inputted from the hidden neuron layer 120 to the output neuron layer 130. The hidden neuron layer 120 and the output neuron layer 130 are fully connected with each other, and two connected neurons in the hidden neuron layer 120 and the output neuron layer 130 have a weight W_{j,k}. For instance, the neuron H2 in the hidden neuron layer 120 and the neuron O₂ in the output neuron layer 130 are connected to each other, and there is a weight W_{2,2} between the neuron H₂ and the neuron O₂. The weight sum from each of the neurons H₁-H_{J} of the hidden neuron layer 120 is regarded as an input of the output neuron layer 130. Each of the neurons O₁-O_{K} in the output neuron layer 130 receives products of every weight sum and the weight W_{j,k}. For example, for neuron O₁, the neuron O₁ receive the weight sum H₁*W_{1,1}+H₂*W_{2,1}+ . . . +H_{J}*W_{J,1}. For neuron O₂, the neuron O₂ receive the weight sum H₁*W_{1,2}+H₂*W_{2,2}+ . . . +H_{J}*W_{J,2}. For neuron O_{K}, the neuron O_{K} receive the weight sum H₁*W_{1,K}+H₂*W_{2,K}+ . . . +X_{I}*W_{J,K}.

As illustratively shown in FIG. 1, the weight sum outputted from each of the neurons O₁-O_{K} of the output neuron layer 130 is regarded as an output of the neural network 100. The outputs from the neurons O₁-O_{K} are compared with target values T₁-T_{K}, respectively. If one of the outputs from the neurons O₁-O_{K} is different from the corresponding target value of the target values T₁-T_{K}, the weight W_{i,j} between the input neuron layer 110 and the hidden neuron layer 120 and the weight W_{j,k} between the hidden neuron layer 120 and the output neuron layer 130 are adjusted until the output and the corresponding target value are the same. In some embodiments, the target value is a predetermined value set to be corresponding to the input data, such that the weight between two adjacent neurons may be trained so as to find out the suitable weight value. In some embodiments, it is referred to as a supervised learning through repeatedly training the weight between two adjacent neuron layers, such that the output and the target are the same, so as to increase classification accuracy. Explained in a different way, the supervised learning is performed through repeatedly training the weight between two adjacent neuron layers, such that the input and the target are the same, so as to increase classification accuracy.

In some embodiments, the neural network 100 discussed in FIG. 1 may be a probabilistic neural network or a stochastic neural network. Here, the term “probabilistic neural network” and “stochastic neural network” may be referred to as a type of neural network that incorporate random variables, which makes them well suited for optimization problems. This can be done by giving the neurons in the network stochastic (randomly determined) weights or transfer functions.

In some embodiments of the present disclosure, at least portions of the neurons as discussed in FIG. 1 may include probabilistic bits (p-bits) that may process multiple states of zeros and ones at one time, where each p-bit rapidly fluctuates between zero and one. For example, as shown in FIG. 1, each of the neurons H₁-H_{J} may include a p-bit that rapidly fluctuates between zero and one, so as to randomly generate a value between zero and one. For example, with respect to the neuron H₁, the neuron H₁ may receive the weight sum of the neurons (e.g., the neurons X₁ to X_{I}) at previous layer as an input of the neuron H₁. Then, the weight sum (e.g., input of the neuron H₁) may be biased with the p-bit of the neuron H₁, in which the p-bit may generate a random variable. Accordingly, the value of the weight sum may be modified with the p-bit (e.g., a random variable), and the modified value is referred to as an output of the neuron H₁, and may be transferred to the neurons at the next layers (e.g., the output neuron layer 130). In some embodiments, each of the p-bit may include a magnetic tunnel junction (MTJ) structure, which will be discussed later.

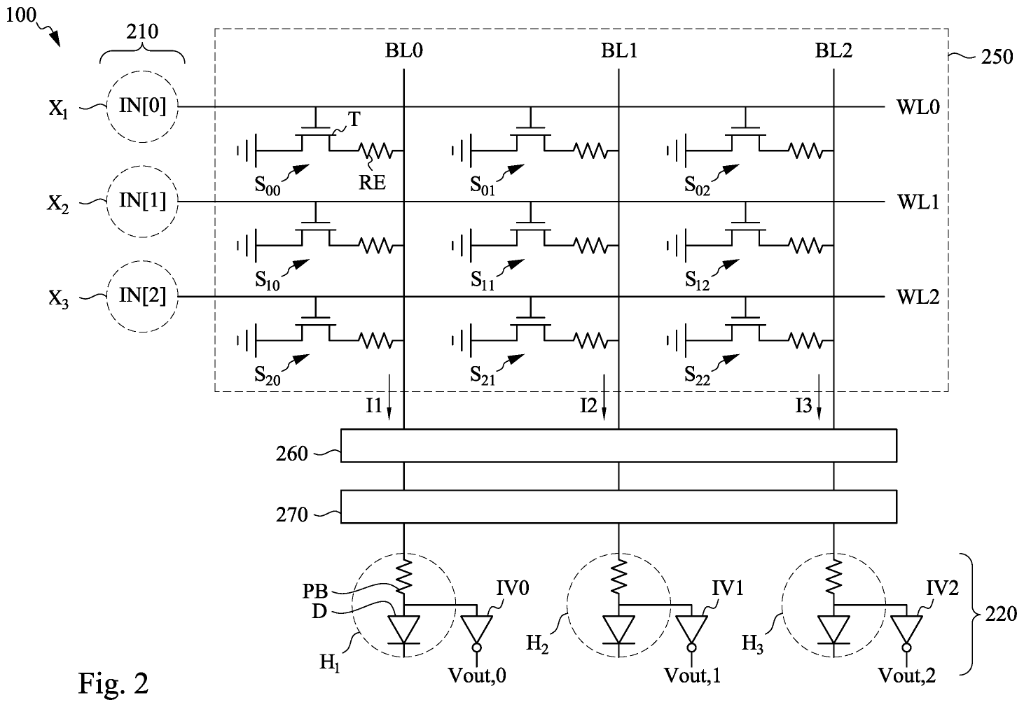

FIG. 2 is a circuit diagram of a neural network in accordance with some embodiments. Shown there is a circuit diagram of a neural network 200. In some embodiments, circuit diagram of the neural network 200 as described in FIG. 2 may be an exemplary aspect of the neural network 100 as described in FIG. 1.

The neural network 200 may include a neuron layer 210 and a neuron layer 220 connected with each other through a weight matrix 250. The neuron layer 210 may be an input neuron layer similar to the input neuron layer 110 as discussed in FIG. 1, and the neuron layer 220 may be a hidden neuron layer similar to the hidden neuron layer 120 as discussed in FIG. 1. In some embodiments, the neuron layer 210 may include neurons X₁, X₂, and X₃, and the neuron layer 220 may include neurons H₁, H₂, and H₃. However, it is understood that the number of neurons are merely used to explain, while more or less neurons may also be applied in the neural network 200 of FIG. 2.

The weight matrix 250 includes a plurality of synapse units (or memory cells), a plurality of bit lines, and a plurality of word lines. The weight matrix 250 includes an array of synapse units. For example, because there are three neurons X₁, X₂, and X₃ and three neurons H₁, H₂, and H₃, there are nine synapse units arranged in a 3×3 array, so as to fully connect the three neurons X₁, X₂, and X₃ to the neurons H₁, H₂, and H₃, respectively. The weight matrix 250 includes synapse units S₀₀, S₀₁, S₀₂, S₁₀, S₁₁, S₁₂, S₂₀, S₂₁, S₂₂.

The weight matrix 250 includes a plurality of word lines WL0, WL1, and WL2, and a plurality of bit lines BL0, BL1, BL2. The word lines WL0, WL1, and WL2 extend laterally along corresponding columns of the array, and the bit lines BL0, BL1, BL2 extend laterally along corresponding rows of the array. Thus, a weight value exists between each of the word line WL0, WL1, and WL2 and each of the bit lines BL0, BL1, BL2 by way of the corresponding one of the synapse units S₀₀, S₀₁, S₀₂, S₁₀, S₁₁, S₁₂, S₂₀, S₂₁, S₂₂.

In some embodiments, the weight value may be adjusted between word line WL0, WL1, and WL2 and the bit lines BL0, BL1, BL2 by applying a proper bias voltage to change a resistive state of the corresponding synapse units S₀₀, S₀₁, S₀₂, S₁₀, S₁₁, S₁₂, S₂₀, S₂₁, S₂₂. For example, different weight values may be set between the between word line WL0, WL1, and WL2 and the bit lines BL0, BL1, BL2, respectively.

In some embodiments, each of the synapse units S₀₀, S₀₁, S₀₂, S₁₀, S₁₁, S₁₂, S₂₀, S₂₁, S₂₂ includes a transistor T and a resistive element RE. The resistive elements RE depicted in FIG. 2 are illustrated as resistors but can be any suitable resistive element. Examples of other types of resistive elements include resistive random access memory (“RRAM”) cells, such as phase-change memory (“PCM”) cells, magnetic random access memory (“MRAM”) cells, and ferroelectric random access memory (“FeRAM”) cells. Certain types of such devices are multi-level resistance devices, i.e., devices capable of having more levels of resistance than binary, high/low values. For example, the resistive elements RE are capable of having four, eight, or higher number of resistance values. In some embodiments, the resistive element RE can also be referred to as weight element.

In some embodiments, the gate of the transistor T is electrically connected to a respective one of the word lines WL0, WL1, and WL2. A first source/drain region of the transistor T is electrically connected the resistive element RE, and a second source/drain region of the transistor T is grounded. On the other hand, a first side of the resistive element RE is electrically connected to the first source/drain region of the transistor T, and a second side of the resistive element RE is electrically a respective one of the bit lines BL0, BL1, and BL2.

In some embodiments, each of the synapse units S₀₀, S₀₁, S₀₂, S₁₀, S₁₁, S₁₂, S₂₀, S₂₁, S₂₂ in the array may be configured to function as synapse function in a deep neural network. For example, each of the synapse units S₀₀, S₀₁, S₀₂, S₁₀, S₁₁, S₁₂, S₂₀, S₂₁, S₂₂ may function as a connection between two digital neurons such that the number of resistive states of the synapse units S₀₀, S₀₁, S₀₂, S₁₀, S₁₁, S₁₂, S₂₀, S₂₁, S₂₂ corresponds to a synaptic weight between the two digital neurons. The synaptic weight may be used to determine a strength or amplitude of a connection between the two digital neurons. For example, a high resistive state of the resistive element RE may correspond to a low synaptic weight (i.e., a larger voltage may be used to connect the two digital neurons) and a low resistive state of the resistive element RE may correspond to a high synaptic weight (i.e., a lower voltage may be used to connect the two digital neurons). Synaptic weights between digital neurons are changed during training of the deep neural networks to achieve a best solution to a problem.

During operation of the neural network 200, elements (values) of the neurons X₁, X₂, and X₃ are fed into the respective word lines WL0, WL1, and WL2 of the weight matrix 250. For example, the neurons X₁, X₂, and X₃ may include values IN[0], IN[1], and IN[2], in which the values IN[0], IN[1], and IN[2] are used as inputs of the weight matrix 250. In greater detail, the values IN[0], IN[1], and IN[2] of the neurons X₁, X₂, and X₃ are applied to the respective word lines WL0, WL1, and WL2 of the weight matrix 250. The voltage transferred to the word lines WL0, WL1, and WL2 may be applied to the gate of the transistor T of the respective one of the synapse units S₀₀, S₀₁, S₀₂, S₁₀, S₁₁, S₁₂, S₂₀, S₂₁, S₂₂, and the transistor T may be turn on and allows current flowing between the first source/drain region of the transistor T and the second source/drain region of the transistor T.

The current flowing between the first source/drain region of the transistor T and the second source/drain region of the transistor T is then multiplied by the conductance of corresponding resistive element RE to produce current that flows downward along the bit lines BL0, BL1, and BL2 to an analog-to-digital conversion unit (ADC) 260.

For example, with respect to the bit line BL0, a first current flowing through the transistor T of the synapse units S₀₀ is multiplied by the conductance of corresponding resistive elements RE of the synapse units S₀₀, a second current flowing through the transistor T of the synapse units S₁₀ is multiplied by the conductance of corresponding resistive elements RE of the synapse units S₁₀, and a third current flowing through the transistor T of the synapse units S₂₀ is multiplied by the conductance of corresponding resistive elements RE of the synapse units S₂₀. The first, second, and third currents are then accumulated by the bit line BL0, and the accumulated current I1 enters the ADC 260.

Similarly, with respect to the bit line BL1, a first current flowing through the transistor T of the synapse units S₀₁ is multiplied by the conductance of corresponding resistive elements RE of the synapse units S₀₁, a second current flowing through the transistor T of the synapse units S₁₁ is multiplied by the conductance of corresponding resistive elements RE of the synapse units S₁₁, and a third current flowing through the transistor T of the synapse units S₂₁ is multiplied by the conductance of corresponding resistive elements RE of the synapse units S₂₁. The first, second, and third currents are then accumulated by the bit line BL1, and the accumulated current I2 enters the ADC 260.

Similarly, with respect to the bit line BL2, a first current flowing through the transistor T of the synapse units S₀₂ is multiplied by the conductance of corresponding resistive elements RE of the synapse units S₀₂, a second current flowing through the transistor T of the synapse units S₁₂ is multiplied by the conductance of corresponding resistive elements RE of the synapse units S₁₂, and a third current flowing through the transistor T of the synapse units S₂₂ is multiplied by the conductance of corresponding resistive elements RE of the synapse units S₂₂. The first, second, and third currents are then accumulated by the bit line BL2, and the accumulated current I3 enters the ADC 260.

The ADC 260 converts the accumulated currents I1, I2, and I3 from the bit lines BL0, BL1, and BL2 into digital signals. These currents are summed up in the bit lines BL0, BL1, and BL2, and then digitized by the ADC 260. The ADC 260 can be any suitable analog-to-digital converters in some embodiments, and any suitable number of ADC 260 can be used.

Shift-and-add component 270 can be any suitable shift-and-add component. The shift-and-add component can include an adder, a register, and a shifter so that the adder can add the output of an ADC 260 to the output of the shifter, and that output can then be stored in the register. Thus, shift-and-add component 270 can receive and accumulate the ADC outputs over multiple cycles in some embodiments.

The outputs at the bottom of shift-and-add components 270 can be the outputs for a layer of the neural network 200, which can then be fed into a new layer of the neural network 200. For example, the output corresponding to the current I1 enters the neurons H₁, the output corresponding to the current I2 enters the neurons H₂, and the output corresponding to the current I3 enters the neurons H₃. Stated another way, the bit lines BL0, BL1, and BL2 are electrically connected to the neurons H₁, H₂, and H₃ through the ADC 260 and the shift-and-add component 270.

Each of the neurons H₁, H₂, and H₃ includes a probabilistic bit (p-bit) PB and a diode D electrically connected to the p-bit PB. In some embodiments, the p-bit PB may include a time-varying resistance. For example, the p-bit PB may include a magnetic tunnel junction (MTJ) structure, in which the MTJ structure with extreme poor retention (e.g., in a range from about 10⁻⁹ s to about 100 s), such that the resistance of the MTJ structure may rapidly change to create a time-varying resistance.

The signal (e.g., voltage) enters the neurons H₁, H₂, and H₃ may be multiplied with the conductance of the p-bit PB, so as to generate a current that flows downward through the p-bit PB toward the diode D. In some embodiments, the diode D is electrically coupled between the p-bit PB and an output of the corresponding one of the neurons H₁, H₂, and H₃. For example, a first side of the diode D is connected to the p-bit PB, and a second side of the diode D is connected to the output of the corresponding one of the neurons H₁, H₂, and H₃, in which a current flowing from the first side of the diode D to the second side of the diode D is referred to as “forward current”, while a current flowing from the second side of the diode D to the first side of the diode D is referred to as “reverse current.”

The neural network 200 further includes invertors IV0, IV1, and IV2 electrically connected to the p-bits PB of the neurons H₁, H₂, and H₃, respectively. Furthermore, the invertors IV0, IV1, and IV2 are electrically coupled to output terminals V_{out,0}, V_{out,1}, and V_{out,2}, respectively.

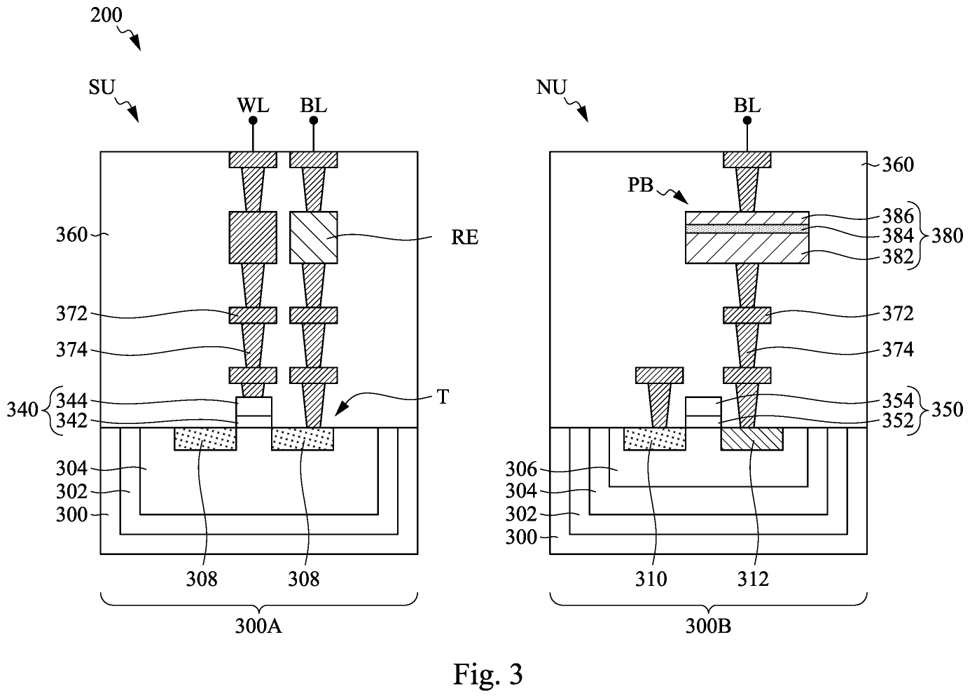

FIG. 3 is a cross-sectional view of a neural network in accordance with some embodiments. It is noted that FIG. 3 illustrates elements of the neural network 200 as discussed in FIG. 2, such elements are labeled the same and relevant details will not be repeated for brevity.

As shown in FIG. 3, the neural network 200 includes a substrate 300. In some embodiments, the substrate 300 may be a semiconductor material and may include known structures including a graded layer or a buried oxide, for example. In some embodiments, the substrate 300 includes bulk silicon. Other materials that are suitable for semiconductor device formation may be used. Other materials, such as germanium, quartz, sapphire, and glass could alternatively be used for the substrate 300.

The substrate 300 may include a first region 300A and a second region 300B. In some embodiments, a synapse unit SU is formed over the first region 300A of the substrate 300, and a neuron unit NU is formed over the second region 300B of the substrate 300. In some embodiments, the synapse units S₀₀, S₀₁, S₀₂, S₁₀, S₁₁, S₁₂, S₂₀, S₂₁, S₂₂ as discussed above with respect to FIG. 2 may include similar structure as the synapse unit SU of FIG. 3. The neurons H₁, H₂, and H₃ as discussed above with respect to FIG. 2 may include similar structure as the neuron unit NU of FIG. 3.

With respect to the first region 300A of the substrate 300, the first region 300A of the substrate 300 includes a deep N-well 302. A P-well 304 is disposed within the deep N-well 302. Source/drain regions 308 are disposed within the P-well 304, in which the source/drain regions 308 are laterally spaced apart from each other. In some embodiments, the substrate 300 and the P-well 304 may be doped with p-type dopants, such as boron (B), gallium (Ga), indium (In), aluminium (Al), or the like. On the other hands, the deep N-well 302 and the source/drain regions 308 may be doped with n-type dopants, such as phosphorus (P), arsenic (As), or antimony (Sb), or the like.

A gate structure 340 is disposed over the first region 300A of the substrate 300, in which the source/drain regions 308 are on opposite sides of the gate structure 340. The gate structure 340 may include a gate dielectric 342 and a gate electrode 344 over the gate dielectric 342. In some embodiments, the gate dielectric 342 may be made of oxide, such as aluminum oxide (Al₂O₃), silicon oxide (SiO₂), or the like. In some embodiments, the gate dielectric 342 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

In some embodiment, the gate electrode 344 may be a conductive material, such as polycrystalline-silicon (polysilicon), poly-crystalline silicon-germanium (poly-SiGe), metallic nitrides, metallic silicides, metallic oxides, and metals. In some other embodiments, the gate electrode 344 may include a work function metal layer and a filling metal over the work function metal layer. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

The gate structure 340, the source/drain regions 308, and the portion of the P-well 304 (e.g., channel region) that is in contact with the gate structure 340 may collectively serve as a transistor T of the synapse unit SU.

A dielectric layer 360 is disposed over the substrate 300 and covering the transistor T. In some embodiments, the dielectric layer 360 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

A plurality of metal lines 372 and metal vias 374 are disposed in the dielectric layer 360 and collectively form an interconnect structure. In some embodiments, the metal lines 372 and metal vias 374 may include Ti, TiN, Mo, Ru, W, Cu, or other suitable conductive materials. Here, the term “metal line” may be referred to as a structure having longest dimension extending laterally, and the term “metal via” may be referred to as a structure having longest dimension extending vertically. The metal via may conduct current vertically and are used to electrically connect two conductive features located at vertically adjacent levels, whereas the metal line may conduct current laterally and are used to distribute electrical signals and power within one level.

In some embodiments, the gate structure 340 of the transistor T is electrically coupled to the interconnect structure formed by the metal lines 372 and the metal vias 374, and is electrically coupled to a word line WL through the interconnect structure. In some embodiments, the word line WL may be the word lines WL0, WL1, or WL2 as discussed above in FIG. 2.

In some embodiments, one of the source/drain region 308 of the transistor T is electrically coupled to the interconnect structure formed by the metal lines 372 and the metal vias 374. Moreover, a resistive element RE of the synapse unit SU is also disposed in the dielectric layer 360 and electrically coupled to the interconnect structure. In greater detail, a first side of the resistive element RE is electrically coupled to the source/drain region 308 of the transistor T through the interconnect structure, and a second side of the resistive element RE is electrically coupled to a bit line BL through the interconnect structure. In some embodiments, the bit line BL may be the bit lines BL0, BL1, or BL2 as discussed above in FIG. 2.

In some embodiments, the resistive element RE may be any suitable resistive element. Examples of resistive elements include resistive random access memory (“RRAM”) cells, such as phase-change memory (“PCM”) devices and magnetic random access memory (“MRAM”) cells, and ferroelectric random access memory (“FeRAM”) cells.

In some embodiments where the resistive element RE includes a RRAM cell. The resistive element RE may include a resistive switching layer sandwiched between a top electrode and a bottom electrode. In some embodiments, the top electrode comprises titanium (Ti) and tantalum nitride (TaN), the bottom electrode comprises titanium nitride (TiN) alone or two layers comprising TiN and TaN, and the resistive switching element includes hafnium dioxide (HfO₂).

In some embodiments where the resistive element RE includes a PCM cell. The resistive element RE may include a phase change element sandwiched between a top electrode and a bottom electrode. The phase change element may include at least one of germanium-antimony-tellurium (GST), GST: N, GST: O and indium-silver-antimony-tellurium (InAgSbTe), or the like.

In some embodiments where the resistive element RE includes a MRAM cell. The resistive element RE may include a magnetic tunnel junction (MTJ) sandwiched between a top electrode and a bottom electrode. The MTJ includes a lower ferromagnetic electrode and an upper ferromagnetic electrode, which are separated from one another by a tunneling barrier layer. In some embodiments, the lower ferromagnetic electrode can have a fixed or “pinned” magnetic orientation, while the upper ferromagnetic electrode has a variable or “free” magnetic orientation, which can be switched between two or more distinct magnetic polarities that each represents a different data state, such as a different binary state. In other implementations, however, the MTJ can be vertically “flipped”, such that the lower ferromagnetic electrode has a “free” magnetic orientation, while the upper ferromagnetic electrode has a “pinned” magnetic orientation.

In some embodiments where the resistive element RE includes a FeRAM cell. The resistive element RE may include a ferroelectric layer sandwiched between a top electrode and a bottom electrode. The ferroelectric layer may include strontium bismuth tantalite (SBT), lead zirconate titanate (PZT), hafnium zirconium oxide (HZO), doped hafnium oxide (Si:HfO₂), other suitable ferroelectric material, or the like.

With respect to the second region 300B of the substrate 300, the second region 300B of the substrate 300 includes a deep N-well 302. A P-well 304 is disposed within the deep N-well 302. An N-well 306 is disposed within the P-well 304. A heavily-doped N-type region 310 and a heavily-doped P-type region 312 are disposed in the N-well 306, in which the heavily-doped N-type region 310 and the heavily-doped P-type region 312 are laterally spaced apart from each other through a portion of the N-well 306. In some embodiments, the substrate 300, the P-well 304, and the heavily-doped P-type region 312 may be doped with p-type dopants, such as boron (B), gallium (Ga), indium (In), aluminium (Al), or the like. On the other hands, the deep N-well 302, the N-well 306, and the heavily-doped N-type region 310 may be doped with n-type dopants, such as phosphorus (P), arsenic (As), or antimony (Sb), or the like. In some embodiments, the heavily-doped N-type region 310 may include dopant concentration in a range from about 10×10¹⁵ cm⁻³ to about 10×10²⁰ cm⁻³. The heavily-doped P-type region 312 may include dopant concentration in a range from about 10×10¹⁵ cm⁻³ to about 10×10²⁰ cm⁻³. In some embodiments, the heavily-doped N-type region 310 and the heavily-doped P-type region 312 may collectively form a diode D of the neuron unit NU. In some embodiments, the heavily-doped N-type region 310 includes a higher dopant concentration (e.g., N-type dopants) than the N-well 306.

A gate structure 350 is disposed over the second region 300B of the substrate 300, in which the heavily-doped N-type region 310 and the heavily-doped P-type region 312 are on opposite sides of the gate structure 350. The gate structure 350 may include a gate dielectric 352 and a gate electrode 354 over the gate dielectric 352. In some embodiments, the gate dielectric 352 may be made of oxide, such as aluminum oxide (Al₂O₃), silicon oxide (SiO₂), or the like. In some embodiments, the gate dielectric 342 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

In some embodiment, the gate electrode 354 may be a conductive material, such as polycrystalline-silicon (polysilicon), poly-crystalline silicon-germanium (poly-SiGe), metallic nitrides, metallic silicides, metallic oxides, and metals. In some other embodiments, the gate electrode 344 may include a work function metal layer and a filling metal over the work function metal layer. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

In some embodiments, the gate structures 340 and 350 may include different materials. For example, the gate structure 340 may be a high-k metal gate structure, which includes a high-k gate dielectric 342 and a metal gate electrode 344. On the other hand, the gate structure 350 may be a poly-gate structure, which includes a gate dielectric 352 made of SiO₂ and a gate electrode 354 made of polysilicon. In some embodiments, the gate structure 340 is an active gate structure of the transistor T, and is electrically coupled to the word line WL through the interconnect structure. On the other hand, the gate structure 350 may be referred to as a dummy gate structure which does not include circuit function. That is, the gate structure 350 is not electrically coupled to other conductive elements such as metal line or metal via in the dielectric layer 360.

The dielectric layer 360 is disposed over the substrate 300 and covering the gate structure 350. A plurality of metal lines 372 and metal vias 374 are disposed in the dielectric layer 360 and collectively form an interconnect structure. In some embodiments, in the cross-sectional view of FIG. 3, an entirety of the top surface of the gate structure 350 is covered by a dielectric material of the dielectric layer 360.

The heavily-doped P-type region 312 is electrically coupled to the interconnect structure formed by the metal lines 372 and the metal vias 374. Moreover, a magnetic tunnel junction (MTJ) structure 380 of a probabilistic bit (p-bit) PB is also disposed in the dielectric layer 360 and electrically coupled to the interconnect structure. In greater detail, a first side of the MTJ structure 380 is electrically coupled to the heavily-doped P-type region 312 through the interconnect structure, and a second side of the MTJ structure 380 is electrically coupled to an input of the neuron unit NU. For example, the second side of the MTJ structure 380 is electrically coupled to a corresponding bit line BL through the ADC 260 and the shift-and-add component 270 (see FIG. 2). In some embodiments, the heavily-doped N-type region 310 is electrically coupled to an output of the neuron unit NU through the interconnect structure formed by the metal lines 372 and the metal vias 374.

The MTJ structure 380 may include a lower ferromagnetic electrode 382 and an upper ferromagnetic electrode 386, which are separated from one another by a tunneling barrier layer 384. In some embodiments, the lower ferromagnetic electrode 382 can have a “fixed” or “pinned” magnetic orientation, while the upper ferromagnetic electrode 384 has a variable or “free” magnetic orientation, which can be switched between two or more distinct magnetic polarities that each represents a different data state, such as a different binary state. That is, the lower ferromagnetic electrode 382 can be referred to as a “fixed layer” or a “pinned layer”, and the upper ferromagnetic electrode 386 can be referred to as a “free layer.” In other implementations, however, the MTJ can be vertically “flipped”, such that the lower ferromagnetic electrode 382 has a “free” magnetic orientation, while the upper ferromagnetic electrode 386 has a “pinned” magnetic orientation. That is, the lower ferromagnetic electrode 382 can be referred to as a “free layer”, and the upper ferromagnetic electrode 386 be referred to as a “fixed layer” or a “pinned layer.”

In some embodiments, the “pinned layer” may include Co/Pt, Fe/Pt, Co/Pd, Fe/Pd multilayer. The “free layer” may include CoFeB, CoFe, FeB, CoB, NiFe, NiFeMo, or the like. The tunneling barrier layer may include MgO, Al₂O₃, or the like. In some embodiments, the MTJ structure 380 may include extreme poor retention (e.g., in a range from about 10⁻⁹ s to about 100 s), such that the resistance of the MTJ structure 380 may rapidly change to create a time-varying resistance, and may serve as a p-bit PB of the neural network 200 as discussed in FIG. 2.

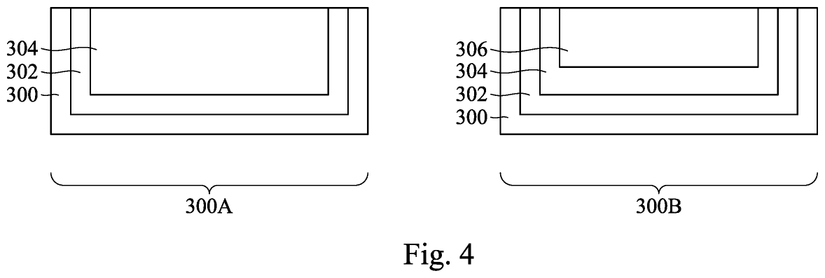

FIGS. 4 to 8 illustrate a neural network in various stages of fabrication in accordance with some embodiments of the present disclosure. In greater detail, FIGS. 4 to 8 illustrate a method for forming the neural network 200 as shown in FIG. 3. It is noted that some elements of FIGS. 4 to 8 have been described above with respect to FIG. 3, such elements are labeled the same, and relevant details will not be repeated for brevity.

Reference is made to FIG. 4. Shown there is a substrate 300, which includes a first region 300A and a second region 300B. Deep N-wells 302 are formed within the first region 300A and the second region 300B of the substrate 300, respectively. In some embodiments, the deep N-wells 302 may be formed using suitable implantation process.

Then, P-wells 304 are formed within the deep N-wells 302 of the first region 300A and the second region 300B, respectively. In some embodiments, the P-wells 304 may be formed using suitable implantation process.

Afterwards, an N-well region 306 is formed within the P-well 304 of the second region 300B. In some embodiments, the N-well region 306 may be formed using suitable implantation process. In some embodiments, during the implantation process of N-well region 306, the first region 300A of the substrate 300 may be masked, such that the P-well 304 of the first region 300A would not undergo the implantation process.

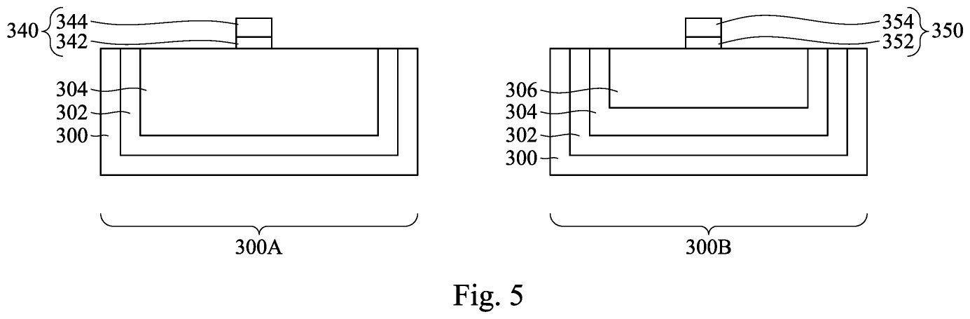

Reference is made to FIG. 5. Gate structures 340 and 350 are formed over the first region 300A and a second region 300B of the substrate 300, respectively. In some embodiments, the gate structures 340 and 350 may be formed by, for example, sequentially depositing a first material of the gate dielectrics 342 and 352 and a second material of the gate electrodes 344 and 354 over the substrate 300, and then patterning the first material and the second material to form the gate structures 340 and 350. That is, the gate structures 340 and 350 are formed at the same time, and may include substantially a same height and a same width.

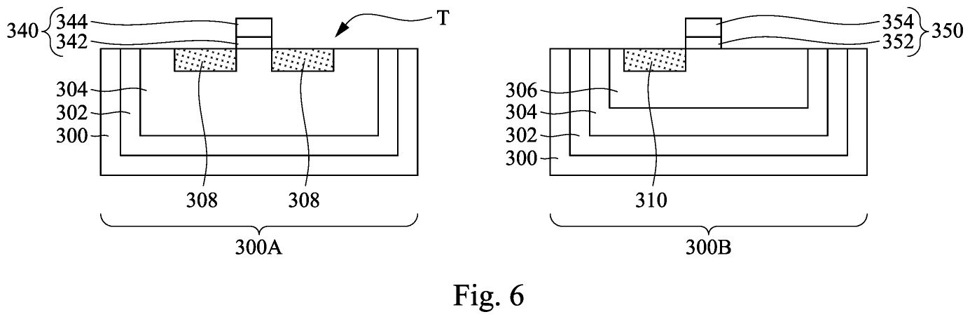

Reference is made to FIG. 6. A first implantation process is performed to form source/drain regions 308 within the first region 300A of the substrate 300, and to form a heavily-doped N-type region 310 within the second region 300B of the substrate 300. In greater detail, the source/drain regions 308 are formed within the first region 300A of the substrate 300 and on opposite sides of the gate structure 340. The heavily-doped N-type region 310 is formed within the second region 300B of the substrate 300 and on one side of the gate structure 350. In some embodiments, a patterned mask (not shown) including openings may be formed over the substrate 300, and the first implantation process may be performed through the openings of the patterned mask to form the source/drain regions 308 and the heavily-doped N-type region 310 in the substrate 300.

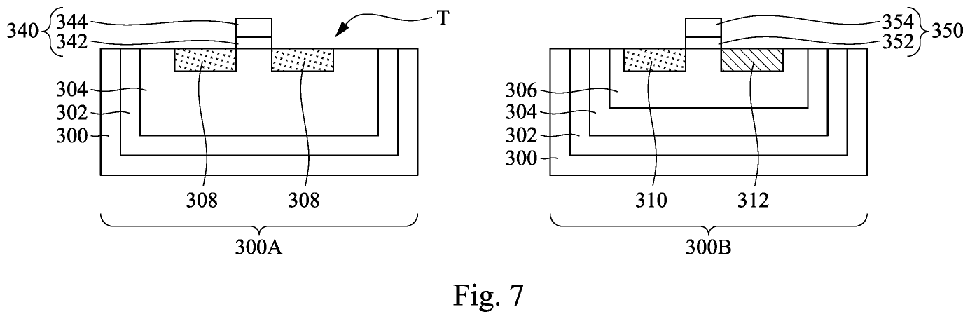

Reference is made to FIG. 7. A second implantation process is performed to form a heavily-doped P-type region 312 within the second region 300B of the substrate 300. In greater detail, the heavily-doped P-type region 312 is formed within the second region 300B of the substrate 300 and on another side of the gate structure 350. In some embodiments, a patterned mask (not shown) including an opening may be formed over the substrate 300, and the second implantation process may be performed through the opening of the patterned mask to form the heavily-doped P-type region 312 in the substrate 300. That is, during performing the second implantation process, the source/drain regions 308 and the heavily-doped N-type region 310 may be masked. It is noted that the order of the first and second implantation processes may be adjusted according to process requirement. That is, the first implantation process may be performed prior to or after the second implantation process, the present disclosure is not limited thereto.

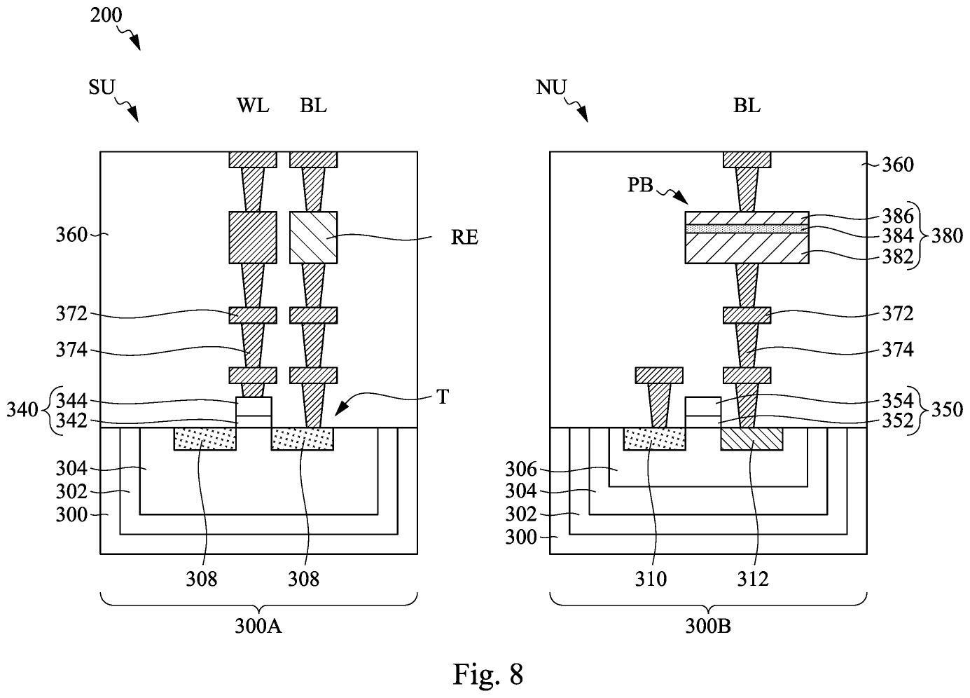

Reference is made to FIG. 8. A dielectric layer 360 is formed over the substrate 300 and covering the gate structures 340 and 350. Metal lines 372 and metal vias 374 are formed in the dielectric layer 360. Moreover, a resistive element RE is formed over the first region 300A of the substrate 300, and a MTJ structure 380 is formed over the second region 300B of the substrate 300.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a neural network. The neural network includes at least one neuron unit. The neuron unit includes a p-bit and a diode. The p-bit is made of a MTJ structure, where the MTJ structure with the nature of stochastic switch makes it a suitable element for p-bit in the application of quantum computing and compute-in-memory. On the other hand, a p-n diode is used in the neuron unit, in which the p-n diode can be used as a switch of the neuron unit, which will improve the flexibility.

In some embodiments of the present disclosure, a neural network circuit includes an input neuron layer comprises a plurality of first neurons. A hidden neuron layer includes a plurality of second neurons, wherein each of the second neurons comprises a probabilistic bit having a time-varying resistance. The probabilistic bit is a magnetic tunnel junction structure comprises a pinned layer, a free layer, and a tunneling barrier layer between the pinned layer and the free layer. A weight matrix comprising a plurality of synapse units, each of the synapse units connecting one of the plurality of first neurons to a corresponding one of the plurality of first neurons.

In some embodiments, each of the second neurons further comprising a diode electrically connected to the probabilistic bit.

In some embodiments, the diode is electrically connected between the probabilistic bit and an output of each of the second neurons.

In some embodiments, the diode includes a heavily-doped N-type region in a substrate, a heavily-doped P-type region in the substrate and adjacent to the heavily-doped N-type region.

In some embodiments, the probabilistic bit is above and electrically connected to the heavily-doped P-type region.

In some embodiments, the heavily-doped N-type region is laterally spaced apart from the heavily-doped P-type region through a portion of an N-well in the substrate.

In some embodiments, the neural network circuit further includes a dummy gate structure over the substrate, wherein the heavily-doped N-type region and the heavily-doped P-type region are on opposite sides of the dummy gate structure.

In some embodiments, the free layer comprises CoFeB, CoFe, FeB, CoB, NiFe, or NiFeMo.

In some embodiments of the present disclosure, a neural network circuit includes an input neuron layer comprises a plurality of first neurons. A hidden neuron layer includes a plurality of second neurons. A weight matrix comprises a plurality of synapse units, each of the synapse units connecting one of the plurality of first neurons to a corresponding one of the plurality of first neurons, wherein each of the synapse units comprises a probabilistic bit having a time-varying resistance and a diode electrically connected to the probabilistic bit. The diode includes a heavily-doped N-type region in a substrate, and a heavily-doped P-type region in the substrate and adjacent to the heavily-doped N-type region.

In some embodiments, the probabilistic bit is a magnetic tunnel junction structure comprising a pinned layer, a free layer, and a tunneling barrier layer between the pinned layer and the free layer.

In some embodiments, the probabilistic bit is above and electrically connected to the heavily-doped P-type region.

In some embodiments, the heavily-doped N-type region is laterally spaced apart from the heavily-doped P-type region through a portion of an N-well in the substrate.

In some embodiments, the neural network circuit includes a dummy gate structure over the substrate, wherein the heavily-doped N-type region and the heavily-doped P-type region are on opposite sides of the dummy gate structure.

In some embodiments, the dummy gate structure comprises polysilicon.

In some embodiments, each of the synapse units comprises a transistor and a resistive element electrically connected to the transistor, and wherein the transistor comprises a gate structure over the substrate, wherein a width of the gate structure is substantially the same as a width of the dummy gate structure. Source/drain regions are in the substrate and on opposite sides of the gate structure.

In some embodiments of the present disclosure, a method for forming a neural network circuit, comprising forming a neuron unit over a substrate, comprising forming a heavily-doped N-type region in the substrate; forming a heavily-doped P-type region in the substrate, wherein the heavily-doped N-type region and the heavily-doped P-type region collective form a diode; and forming a magnetic tunnel junction structure over and electrically connected to the heavily-doped P-type region; forming a synapse unit over the substrate, the synapse unit is electrically connected to the neuron unit, wherein forming the synapse unit comprising forming a transistor over the substrate; and forming a resistive element electrically connected to the transistor.

In some embodiments, forming the neuron unit further comprises forming a dummy gate structure over the substrate prior to forming the heavily-doped N-type region and the heavily-doped P-type region, wherein the forming the heavily-doped N-type region and the heavily-doped P-type region are formed on opposite sides of the dummy gate structure.

In some embodiments, forming the transistor comprises forming a gate structure over the substrate, wherein the gate structure and the dummy gate structure are formed at a same time; and forming source/drain regions in the substrate and on opposite sides of the source/drain regions.

In some embodiments, the source/drain regions and the heavily-doped N-type region are formed at a same time.

In some embodiments, the magnetic tunnel junction structure comprises a pinned layer, a free layer, and a tunneling barrier layer between the pinned layer and the free layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A neural network circuit, comprising:
an input neuron layer comprises a plurality of first neurons;
a hidden neuron layer comprises a plurality of second neurons, wherein each of the second neurons comprises a probabilistic bit having a time-varying resistance, and the probabilistic bit is a magnetic tunnel junction structure comprises:
a pinned layer;
a free layer; and
a tunneling barrier layer between the pinned layer and the free layer; and
a weight matrix comprising a plurality of synapse units, each of the synapse units connecting one of the plurality of first neurons to a corresponding one of the plurality of first neurons.

2. The neural network circuit of claim 1, wherein each of the second neurons further comprising a diode electrically connected to the probabilistic bit.

3. The neural network circuit of claim 2, wherein the diode is electrically connected between the probabilistic bit and an output of each of the second neurons.

4. The neural network circuit of claim 2, wherein the diode comprises:
a heavily-doped N-type region in a substrate; and
a heavily-doped P-type region in the substrate and adjacent to the heavily-doped N-type region.

5. The neural network circuit of claim 4, wherein the probabilistic bit is above and electrically connected to the heavily-doped P-type region.

6. The neural network circuit of claim 4, wherein the heavily-doped N-type region is laterally spaced apart from the heavily-doped P-type region through a portion of an N-well in the substrate.

7. The neural network circuit of claim 4, further comprising a dummy gate structure over the substrate, wherein the heavily-doped N-type region and the heavily-doped P-type region are on opposite sides of the dummy gate structure.

8. The neural network circuit of claim 1, wherein the free layer comprises CoFeB, CoFe, FeB, CoB, NiFe, or NiFeMo.

9. A neural network circuit, comprising:
an input neuron layer comprises a plurality of first neurons;
a hidden neuron layer comprises a plurality of second neurons; and
a weight matrix comprising a plurality of synapse units, each of the synapse units connecting one of the plurality of first neurons to a corresponding one of the plurality of first neurons, wherein each of the synapse units comprises a probabilistic bit having a time-varying resistance and a diode electrically connected to the probabilistic bit, and wherein the diode comprises:
a heavily-doped N-type region in a substrate; and
a heavily-doped P-type region in the substrate and adjacent to the heavily-doped N-type region.

10. The neural network circuit of claim 9, wherein the probabilistic bit is a magnetic tunnel junction structure comprises:
a pinned layer;
a free layer; and
a tunneling barrier layer between the pinned layer and the free layer.

11. The neural network circuit of claim 9, wherein the probabilistic bit is above and electrically connected to the heavily-doped P-type region.

12. The neural network circuit of claim 9, wherein the heavily-doped N-type region is laterally spaced apart from the heavily-doped P-type region through a portion of an N-well in the substrate.

13. The neural network circuit of claim 9, further comprising a dummy gate structure over the substrate, wherein the heavily-doped N-type region and the heavily-doped P-type region are on opposite sides of the dummy gate structure.

14. The neural network circuit of claim 13, wherein the dummy gate structure comprises polysilicon.

15. The neural network circuit of claim 13, wherein each of the synapse units comprises a transistor and a resistive element electrically connected to the transistor, and wherein the transistor comprises:
a gate structure over the substrate, wherein a width of the gate structure is substantially the same as a width of the dummy gate structure; and
source/drain regions in the substrate and on opposite sides of the gate structure.

16. A method for forming a neural network circuit, comprising:
forming a neuron unit over a substrate, comprising:
forming a heavily-doped N-type region in the substrate;
forming a heavily-doped P-type region in the substrate, wherein the heavily-doped N-type region and the heavily-doped P-type region collective form a diode; and
forming a magnetic tunnel junction structure over and electrically connected to the heavily-doped P-type region; and
forming a synapse unit over the substrate, the synapse unit is electrically connected to the neuron unit, wherein forming the synapse unit comprising:
forming a transistor over the substrate; and
forming a resistive element electrically connected to the transistor.

17. The method of claim 16, wherein forming the neuron unit further comprises:
forming a dummy gate structure over the substrate prior to forming the heavily-doped N-type region and the heavily-doped P-type region, wherein the forming the heavily-doped N-type region and the heavily-doped P-type region are formed on opposite sides of the dummy gate structure.

18. The method of claim 17, wherein forming the transistor comprises:
forming a gate structure over the substrate, wherein the gate structure and the dummy gate structure are formed at a same time; and
forming source/drain regions in the substrate and on opposite sides of the source/drain regions.

19. The method of claim 18, wherein the source/drain regions and the heavily-doped N-type region are formed at a same time.

20. The method of claim 16, wherein the magnetic tunnel junction structure comprises:
a pinned layer;
a free layer; and
a tunneling barrier layer between the pinned layer and the free layer.
